(19) United States
(12) Patent Application Publication
(10) Pub. No.: US 2005/0156330 A1
(43) Pub. Date: Jul. 21, 2005

(54) Through-wafer contact to bonding pad

(76) Inventor: James M. Harris, Menlo Park, CA (US)

Correspondence Address: James M. Harris, 969 Rose Avenue, Menlo Park, CA, 94025-4420, US

(21) Appl. No.: 10/761,639

(22) Filed: Jan. 21, 2004

(51) Int. Cl. H01L 23/48; H01L 21/44

(52) U.S. Cl. 257/781; 438/614

(57) ABSTRACT

An integrated circuit with conductive channels connecting the bonding pads to alternative surfaces of the IC chip is disclosed. Typically the channels would be formed by reactive ion etching, passivated and then filled with copper or other conductive material. The channels may be formed at alternative points in the wafer processing flow depending on the requirements of the IC. Alternatively the channels may be used for heat sinks; in this case the channel would connect a chip “hot spot” with a conductive package member.

### FIELD OF INVENTION

The invention described herein relates generally to semiconductor integrated circuit manufacturing processes. In particular, the invention relates to improved methods of making contact to the bonding pads for side or backside connection.

### BACKGROUND OF INVENTION

A critical step in the manufacture of all integrated circuit devices is known as “packaging” and involves mechanical and environmental protection of the device chip as well as making electrical interconnection between locations on the silicon chip, known as bonding pads, and external electrical terminals. At present three main technologies are employed for making electrical connections to the integrated circuit: wire bonding, tape automatic bonding (TAB) and flip chip. All three technologies have deficiencies. Chip scale size packages require very small footprints to achieve space improvements. New interconnection techniques are needed to achieve even smaller footprints.

Prior art uses various means of connecting the bonding pads via external connections to the back of the chip. These external connections are typically formed in the final stages of manufacture of the integrated circuit. Additional background is found in U.S. Pat. No. 6,040,235 and U.S. 2003/0209772; both are incorporated herein by reference. FIG. 1 shows the prior art as described in U.S. 2003/0209772.

A need exists for a more compact and less costly manufacturing techniques for making alternate contact methods to the bonding pads during IC processing.

### SUMMARY OF INVENTION

Invention resides in the unique design of a process for making contact to the bonding pads internal to the integrated circuit die at the wafer level. Using standard IC processes, and simultaneous with other IC processes being carried out, conductive channels are formed in the silicon wafer which electrically connect the bonding pads to alternative locations on either the back of the wafer or the edge of the integrated circuit chip which will be exposed after singulation.

### BRIEF DESCRIPTION OF DRAWINGS

FIG. 1 is an example of the prior art.

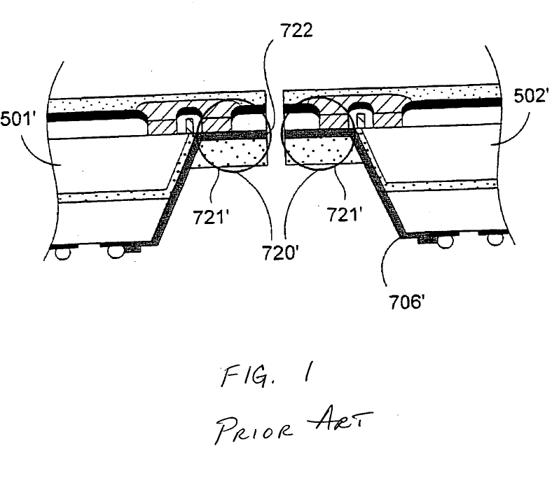

FIGS. 2A and 2B are schematics of one embodiment of the invention.

FIGS. 3A and 3B are schematics of an alternate embodiment.

FIGS. 4A, 4B and 4C are schematics of an alternative embodiment.

FIGS. 5A and 5B are schematics of a still alternate embodiment.

FIG. 6 are exemplary process steps for one embodiment.

### DETAILED DESCRIPTION OF EMBODIMENTS

Using reactive ion etching techniques high aspect ratio features are routinely made with current IC technology. Copper metallization technology includes not only the ability to deposit seed layers but also to deposit the conductor layer and form barrier layers to prevent the diffusion of the copper into the active device regions as well as isolate it electrically from other circuit elements. All metallization schemes require a barrier material between the conductor and the device material to prevent diffusion of the conductor into the active circuit element region with subsequent degradation of circuit performance as well as maintain electrical isolation. Silicon dioxide is the most common barrier material for non-copper based metallization systems; SiO2 has the benefit of providing simultaneously electrical and material isolation. The advent of copper metallization has required extensive research to develop tantalum nitride based and other barrier systems suitable for copper.

The advent of atomic layer deposition and focused physical vapor deposition processes has allowed vertical wall features to be coated with uniform films of varying type and utility. MEM's technology teaches alternative processes for making channels in a wafer, both vertically and horizontally. Typically, these processes involve high speed reactive ion etching or wet etching techniques. Bringing these various processes together allows the current invention to be enabled.

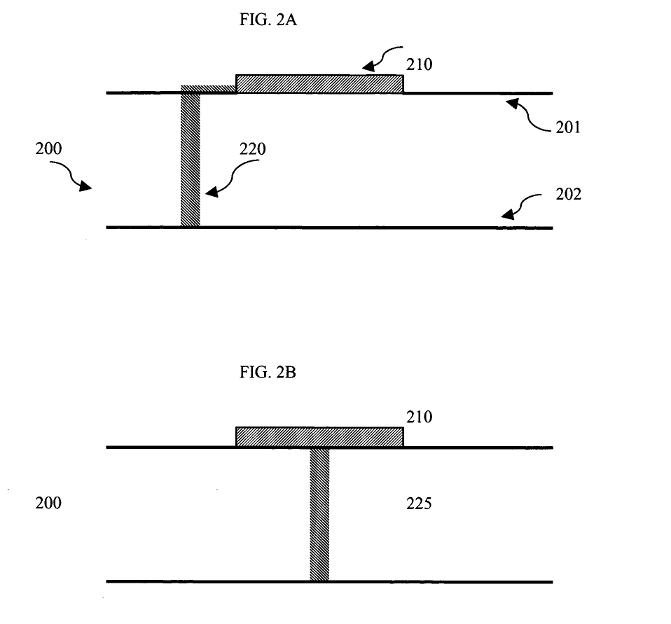

One embodiment of the invention as sketched in FIGS. 2A and 2B shows a vertical channel (220) formed through the wafer (200) and either adjacent (220) or underneath (225) a bonding pad (210). This channel may be formed in one step or a combination of steps as the integrated circuit itself is being built. In one embodiment the channel is formed prior to initial copper metallization. In this way barrier formation and seed layer formation in the channel is carried out simultaneous with copper metallization formation. The channel, having been filled with copper, then electrically connects the bonding pad on the front side (201) of the wafer to the back of the wafer (202). The size of the channel and copper cross section must be appropriate to the current carrying requirements or voltage drop requirements of the bonding pad itself. One knowledgeable in the art will understand the requirement.

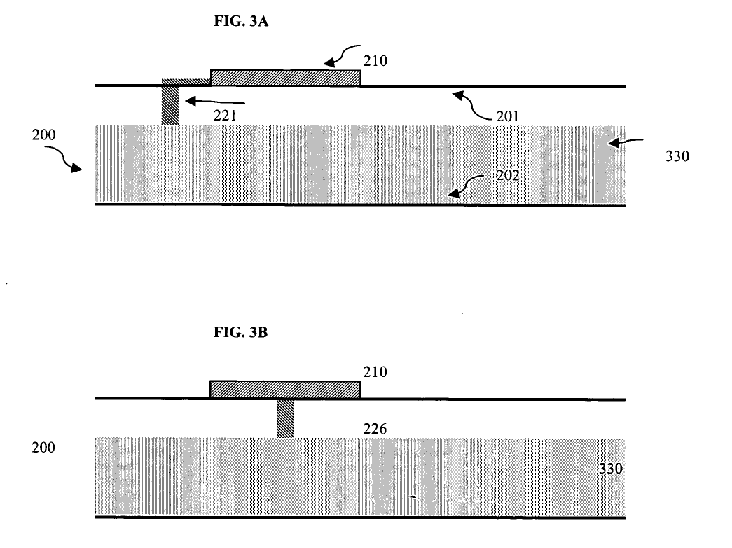

An alternative embodiment is shown in FIGS. 3A and 3B. In this example the conductive channel (220 or 225) extends only partially through the wafer. In this case the back surface of the wafer undergoes a polishing step to remove sufficient material (330) to expose the conductive channel. Typically, chemical-mechanical polishing is used for this process. The advantage of this embodiment is that the conductive channel may need to be only 20 to 50 microns deep; a drawback is the CMP step. A cover plate may be added to the top of the wafer for mechanical handling purposes prior to the polish step if desired.

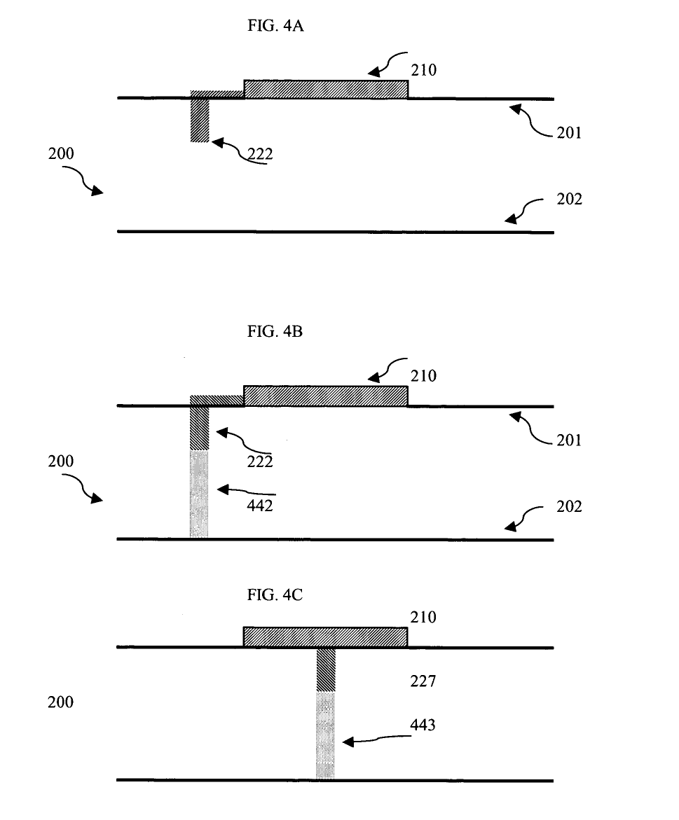

An alternative embodiment is shown in FIG. 4A, B and C. In this example the conductive channel is formed in at least two steps, each extending only partially through the wafer. In one variation the top side channel connection (222) is formed first and the back side channel connection (442) is formed in subsequent processing. Alternatively the back side conductive channels may be formed first and then the front side. For instance, at the point in the process when the active device elements have been formed and the first layer metallization has been covered with a passivating layer but prior to opening the vias to the first layer contacts may be a convenient point to form the backside conductive channels. In this state the wafer is well protected from most processes which may be considered for making the backside channels, giving the IC process engineer more latitude in choosing a compatible process flow. Then as the subsequent metal layers are built up on the front side of the wafer the front side conductive channel can be formed as is convenient.

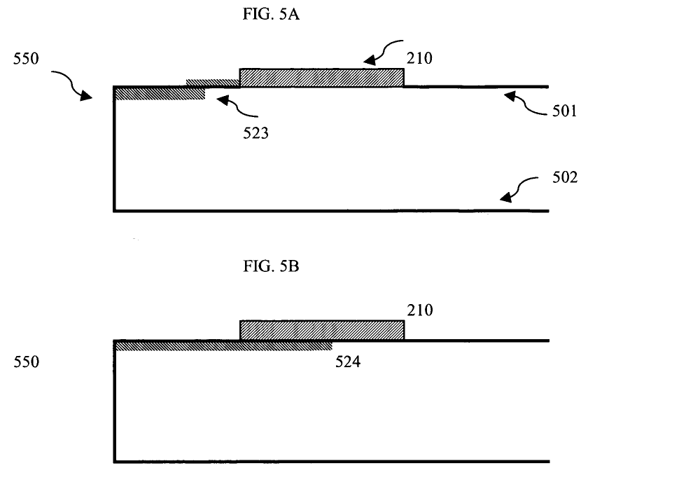

FIGS. 5A and 5B show an alternative embodiment placing the contacts (223) at the edge of the singulated IC chip (550). In this case the conductive channel is stilled formed during the IC processing; the contact region is exposed only after chip singulation. (501) is the top or front surface of the chip and 502 is the back or bottom surface. As with all of the embodiments the conductive channel may be placed to make an edge contact, as with (523) or an under the pad contact as with (524).

One knowledgeable in the art can see that many alternative processing points can be chosen to put in a combination of front side, back side and CMP steps depending on the IC process flow and the constraints placed on the process engineer. The fundamental idea of the invention remains consistent regardless of the particular process flow.

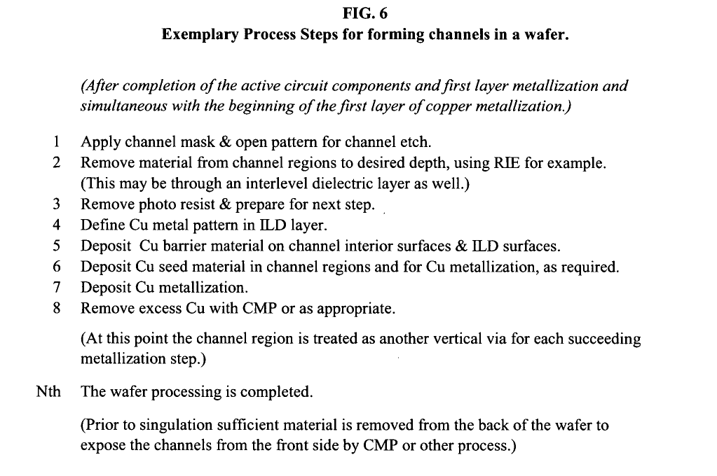

FIG. 6 is one example of a sequence of process steps for achieving the through wafer bonding pad connections. The example process is not meant to be the exact sequence of steps used in every instance but to provide sufficient insight into the invention that one skilled in the art can reproduce the structure.

Alternative uses for these conductive channels can be envisioned. For example, copper is a better thermal conductor than silicon. A copper channel, or channels, may be placed in close proximity to a region of the IC chip which is generating an excessive amount of heat. In this way the heat is “piped” to the backside of the die and removed by contact with the packaging material. Frequently die are mounted on diamond interposers placed between the chip and the package material to facilitate heat conduction away from the die. One embodiment is that the heat sinking channels are thermally connected to a diamond interposer to improve heat removal from the IC. Alternative ways of performing this task are obvious to those skilled in the art. All of the alternatives will rely on a thermally conductive channel comprised of material with a thermal conductivity higher than silicon and, as required, with a suitable barrier material between the conductive material and the silicon.

It is apparent that in a wafer of this construction the term “bonding pad” is used for historical purposes only. Maintaining a region on the chip which can be used as a wire bonding pad or bump attachment location is a convenience that may not be necessary. In an alternative embodiment the “bonding pad” becomes a location for the conductive channel to electrically connect to the desired circuit elements without the necessity of being a functional wire bonding pad. Of course this embodiment requires an alternative scheme for electrical testing, also known as “wafer sorting”, at the wafer level. One alternative would be to make contact through the conductive channels on the back of the wafer, as opposed to using the wire bond pads on the front.

In using this concept certain design rules must be established for through hole sizes, isolation material and separation distances from active components. These rules are a function of the minimum feature size of the integrated circuit and overall process capability of the particular manufacturing facility.

Foregoing described embodiments of the invention are provided as illustrations and descriptions. They are not intended to limit the invention to precise form described. In particular, it is contemplated that functional implementation of invention described herein may be implemented equivalently in hardware, software, firmware, and/or other available functional components or building blocks. Other variations and embodiments are possible in light of above teachings, and it is thus intended that the scope of invention not be limited by this Detailed Description, but rather by claims following.

1. An integrated circuit formed on a semiconductor wafer having a first surface separated from a second surface and edges, comprising:
a region separating said integrated circuit from neighboring integrated circuits;
one or more contact pads within said integrated circuit on said first surface;
one or more electrically conductive materials placed in communication with said bonding pad; and
said electrically conductive materials making contact to said second surface or said region.

2. The integrated circuit of claim 1 wherein a barrier material is placed between said conductive materials and said integrated circuit body.

3. The integrated circuit of claim 1 wherein said conductive material surrounded by said barrier material is contained in a channel in said semiconductor wafer and said channel connects said front surface bonding pad to said second surface or said separation region.

4. An integrated circuit formed on a semiconductor wafer having a first surface separated from a second surface by a known thickness and edges, comprising:
a region separating said integrated circuit from neighboring integrated circuits;
one or more contact pads within said integrated circuit on said first surface;
one or more electrically conductive materials placed in communication with said bonding pad; and
said electrically conductive materials being in a channel in the direction of said second surface or said region.

5. The integrated circuit of claim 4 wherein a barrier material is placed between said conductive materials and said channel surfaces.

6. The integrated circuit of claim 5 wherein said conductive material surrounded by said barrier material is contained in a channel in said semiconductor wafer and said channel connects said front surface bonding pad to said second surface or said separation region after a portion of said known thickness has been removed.

7. A method for producing integrated circuit devices including the steps of:
producing a plurality of integrated circuits on a wafer having first and second planar surfaces, each of the integrated circuits including regions for a multiplicity of bonding pads;
forming channels connecting said bonding pad regions on said first surface to said second surface;
forming a barrier on surface of said channels;
depositing an electrically conductive material on said barriers in said channels;
forming bonding pads in said bonding pad regions; and
forming electrical connections between said electrically conductive material and said bonding pads.

8. A method for producing integrated circuit devices including the steps of:
producing a plurality of integrated circuits on a wafer having first and second planar surfaces, each of the integrated circuits including regions for a multiplicity of bonding pads;
forming channels in said bonding pad regions on said first surface extending a partial distance toward said second surface;
forming a barrier on surface of said channels;
depositing an electrically conductive material on said barriers in said channels;
forming bonding pads in said bonding pad regions;
forming electrical connections between said electrically conductive material and said bonding pads; and
thinning said wafer from said second surface until said conductive material in said channels is exposed on the thinned wafer's newly formed second surface.

9. A method for producing integrated circuit devices including the steps of:
producing a plurality of integrated circuits on a wafer having first and second planar surfaces, each of the integrated circuits including regions for a multiplicity of active circuit elements;
forming channels from said second surface extending a partial distance toward said first surface in thermal communication with said active device regions;
forming a barrier on surface of said channels; and
depositing a thermally conductive material on said barriers in said channels.

10. The method of claim 9 wherein said thermally conductive material has a thermal conductivity higher than the wafer material.

11. A mask set for producing integrated circuit devices comprising regions for:
producing a plurality of integrated circuits on a wafer having first and second planar surfaces, each of the integrated circuits including regions for a multiplicity of bonding pads;
forming channels in said bonding pad regions on said first surface extending toward said second surface; and
forming electrical connections between said channel regions and said bonding pad regions.

12. A design file on computer readable medium containing design rules for producing integrated circuit devices on a wafer having first and second planar surfaces, each of the integrated circuits including regions for a multiplicity of bonding pads and said rules comprising:
guide lines for placing channels in said bonding pad regions on said first surface extending toward said second surface; and
guide lines for interconnecting said channels to said bonding pad regions.
